(19) United States
(12) Patent Application Publication
(10) Pub. No.: US 2026/0143950 A1
(43) Pub. Date: May 21, 2026

(54) DISPLAY DEVICE

(71) Applicant: LG Display Co., Ltd., Seoul (KR)

(72) Inventors: JeongWoo LEE, Uijeongbu-si (KR); Gotae KIM, Goyang-si (KR)

(73) Assignee: LG Display Co., Ltd., Seoul (KR)

(21) Appl. No.: 19/267,159

(22) Filed: Jul. 11, 2025

(30) Foreign Application Priority Data
Nov. 19, 2024 (KR) 10-2024-0165269

(51) Int. Cl. H10K 59/80

(52) U.S. Cl. CPC H10K 59/873

(57) ABSTRACT

A display device according to an exemplary embodiment of the present disclosure includes a display panel including a plurality of sub pixels, a cover glass disposed above the display panel, the cover glass comprising a first area and a second area, and a metal plate disposed below the display panel, the metal plate comprising a first metal plate corresponding to the first area and a second metal plate corresponding to the second area. The first metal plate and the second metal plate may be forcibly fitted together in a fastening area between the first area and the second area to mechanically couple the first metal plate and the second metal plate. By doing this, separation between the cover glass and the display panel in a local curvature portion may be suppressed.

### CROSS-REFERENCE TO RELATED APPLICATIONS

This application claims the priority of Korean Patent Application No. 10-2024-0165269 filed on Nov. 19, 2024, in the Korean Intellectual Property Office, the disclosure of which is incorporated herein by reference.

### BACKGROUND

### Technical Field

The present disclosure relates to a display device, and more particularly, to a display device with a side bending structure.

### Description of the Related Art

As it enters the information era, a field of a display device which visually expresses electrical information signals has been rapidly developed and studies are continued to improve performances of various display devices, such as a thin-thickness, a light weight, and low power consumption.

Among various display devices, an electroluminescent display device which is represented by an organic light emitting display device is a self-emitting display device so that a separate light source is not necessary so that it can be manufactured to have a light weight and a small thickness. Further, the electroluminescent display device is advantageous not only in terms of power consumption due to the low voltage driving, but also in terms of color implementation, a response speed, a viewing angle, a contrast ratio (CR).

Design elements of the display devices are becoming important factors to determine purchase of the display devices so that studies and development are being conducted to provide the display device with various shapes.

As an example of a display device with an improved design, there may be a curved display device in which a side portion of the display device is bent or a display device having a side bending structure. A display device with such a side bending structure is actively being studied and developed because the overall aesthetics of the display device are improved as the side is bent, and additional functions can be implemented by displaying images on the bent side portion.

In the meantime, in the display device having a side bending structure, the bent display panel cannot maintain the bent state due to a local curvature of a specific portion so that there is an issue that the separation occurs between a cover glass and a display panel in a portion having a local curvature.

### BRIEF SUMMARY

An object to be achieved by the present disclosure is to provide a display device having a side bending structure in which a side portion is bent.

Another object to be achieved by the present disclosure is to provide a display device having a side bending structure in which the separation between the cover glass and the display panel in the local curvature portion is suppressed.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a display device includes a display panel including a plurality of sub pixels, a cover glass disposed above the display panel, the cover glass comprising a first area and a second area, and a metal plate disposed below the display panel, the metal plate comprising a first metal plate corresponding to the first area and a second metal plate corresponding to the second area. The first metal plate and the second metal plate may be forcibly fitted together in a fastening area between the first area and the second area to mechanically couple the first metal plate and the second metal plate.

According to another aspect of the present disclosure, a display device includes a display panel including a plurality of sub pixels, a cover glass disposed above the display panel, the cover glass comprising a first area having a first curvature and a second area having a second curvature greater than the first curvature, and a metal plate disposed below the display panel, the metal plate comprising a first metal plate corresponding to the first area and a second metal plate corresponding to the second area. The first metal plate and the second metal plate may be forcibly fitted together and fastened in a fastening area between the first area and the second area.

Other detailed matters of the exemplary embodiments are included in the detailed description and the drawings.

According to the present disclosure, separate metal plates are attached to a rear surface of the display panel to forcibly fit them together so that a specific radius of curvature may be maintained without external force. Therefore, the separation between the cover glass and the display panel in the local curvature portion may be suppressed.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a perspective view of a display device according to an exemplary embodiment of the present disclosure;

FIG. 2 is a cross-sectional view of a display device taken along the line I-I′ of FIG. 1;

FIG. 3 is a cross-sectional view of a display panel of FIG. 2;

FIGS. 4A and 4B are cross-sectional views of a display device taken along the line II-II′ of FIG. 1;

FIG. 5 is a cross-sectional view of an organic light emitting diode layer taken along the line III-III′ of FIG. 1;

FIG. 6 is a rear view of a display device of FIG. 4B;

FIG. 7A is a rear view of a first adhesive layer and a resin layer of FIG. 4A;

FIG. 7B is a rear view of a first adhesive layer and a resin layer of FIG. 4B;

FIGS. 8A and 8B are views enlarging a part A of FIG. 6;

FIG. 9 is a perspective view enlarging a part A of FIG. 6;

FIG. 10A is a cross-sectional view of a metal plate taken along the line IV-IV′ of FIG. 9;

FIG. 10B is a cross-sectional view of a metal plate taken along the line V-V′ of FIG. 9;

FIGS. 11A and 11B are cross-sectional views of a metal plate according to another exemplary embodiment of the present disclosure;

FIGS. 12A and 12B are views illustrating a part of a metal plate according to still another exemplary embodiment of the present disclosure;

FIGS. 13A and 13B are views illustrating a part of a metal plate according to still another exemplary embodiment of the present disclosure;

FIGS. 14A to 14F are cross-sectional views sequentially illustrating a method of attaching a display panel to a curved cover glass according to an exemplary embodiment of the present disclosure; and

FIGS. 15A to 15D are cross-sectional views illustrating a part of another method of attaching a display panel to a curved cover glass according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

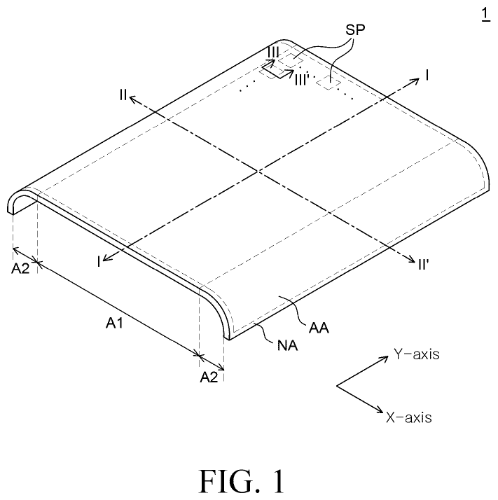

FIG. 1 is a perspective view of a display device according to an exemplary embodiment of the present disclosure.

Referring to FIG. 1, a display device 1 according to an exemplary embodiment of the present disclosure includes a display panel having a substrate to be described below and a plurality of sub pixels disposed on the substrate.

The display panel of such a display device 1 may be various types of display panels, such as an organic light emitting display panel or a liquid crystal display panel. Hereinafter, for the convenience of description, an organic light emitting display panel will be described as an example.

The display device 1 according to the exemplary embodiment of the present disclosure may include a first area A1 and a second area A2.

The first area A1 may be a flat area and the second area A2 may be a curved area. The first area A1 may be a flat portion and the second area A2 may be a curved portion or a bent portion.

For example, the second area A2 is disposed in both sides of the first area A1 so that the farther from the first area A1, the larger the gradient. However, the present disclosure is not limited thereto and each of the second areas A2 disposed in both side portions of the first area A1 may be disposed with different curvatures. Further, the second area A2 may be disposed on only one side surface of the first area A1 or may be disposed on all sides of the first area A1. For example, when the first area A1 has four sides, the second area A2 may be disposed in one or more sides, among four sides or may be disposed in all four sides.

As described above, the display device in which a curved portion is disposed on a side may be referred to as a display device having a side bending structure or a curved display device.

The display device 1 according to the exemplary embodiment of the present disclosure may include an active area AA and a non-active area NA. The active area AA and the non-active area NA may be disposed in the first area A1 and the second area A2 of the display device 1, respectively.

The active area AA is an area in which an image is displayed in the display device 1 and a display element and various driving elements for driving the display element may be disposed in the active area AA.

For example, the display element may be configured by a light emitting diode including a first electrode, an emission layer, and a second electrode. Further, various driving elements for driving the display element, such as a thin film transistor, a capacitor, or a wiring line may be disposed in the active area AA.

A plurality of sub pixels SP may be included in the active area AA. The sub pixel SP is a minimum unit which configures a screen and each of the plurality of sub pixels SP may include a light emitting diode and a driving circuit. The plurality of sub pixels SP may emit light having different wavelengths. For example, the plurality of sub pixels SP may include at least one red sub pixel, a green sub pixel, and a blue sub pixel, but it is not limited thereto and the plurality of sub pixels SP may further include a white sub pixel.

The driving circuit of the sub pixel SP is a circuit for controlling the driving of the light emitting diode. For example, the driving circuit may be configured to include a thin film transistor and a capacitor, but is not limited thereto.

The non-active area NA is an area where no image is displayed and various components for driving the plurality of sub pixels SP disposed in the active area AA may be disposed in the non-active area NA. For example, a driving IC which supplies a signal for driving the plurality of sub pixels SP and a flexible film may be disposed.

The non-active area NA may be an area which encloses the active area AA as illustrated in FIG. 1. However, it is not limited thereto, and for example, the non-active area NA may be an area extending from the active area AA.

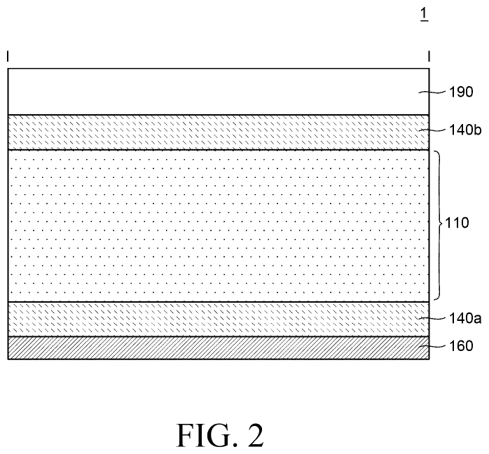

FIG. 2 is a cross-sectional view of a display device taken along the line I-I′ of FIG. 1.

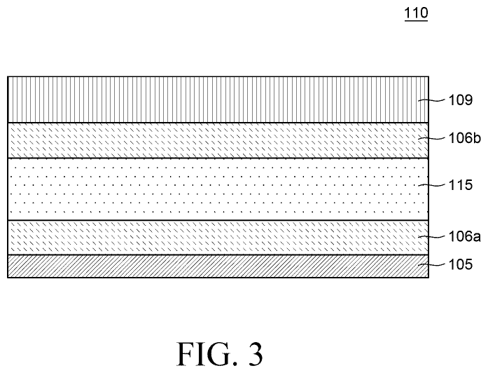

FIG. 3 is a cross-sectional view of a display panel of FIG. 2.

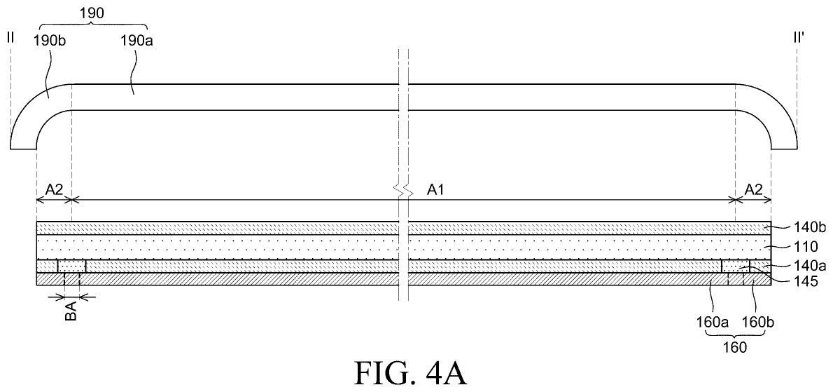

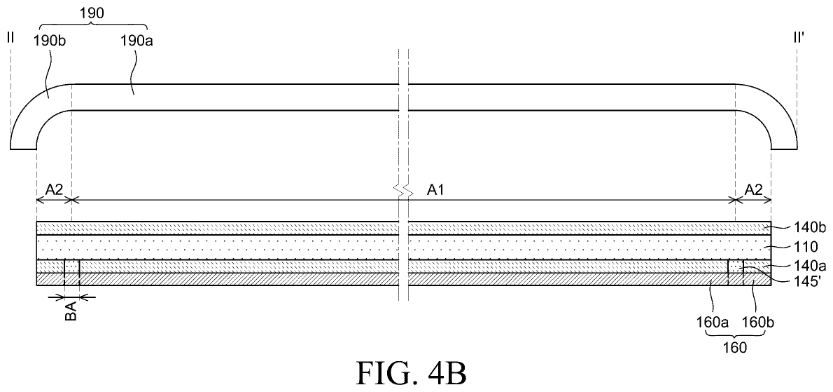

FIGS. 4A and 4B are cross-sectional views of a display device taken along the line II-II′ of FIG. 1.

FIG. 2 illustrates a cross-section structure of the display device 1 of FIG. 1 taken along an X-axis direction as an example and FIG. 3 illustrates a cross-sectional structure of a display panel 110 of FIG. 2.

FIGS. 4A and 4B illustrate various examples of a cross-sectional structure of the display device 1 of FIG. 1 taken along a Y-axis direction, and for the convenience of description, illustrate a display panel 110 before being bent.

Referring to FIG. 2, the display device 1 according to the exemplary embodiment of the present disclosure may include a display panel 110, a cover glass 190, and a metal plate 160.

The display panel 110 according to the exemplary embodiment of the present disclosure may be a flexible display panel and the overall display panel 110 has excellent elasticity and flexibility so that it may not only maintain a flat state, but also may be freely curved or bent. As described above, in the following description, the display panel 110 will be described as a flexible organic light emitting display panel, but the present disclosure is not limited thereto and may also be applied to another display panel which ensures flexibility in the same way.

The cover glass 190 may be disposed on the top of the display device 1.

The cover glass 190 protects an upper portion of the display panel 110 and may be formed of a tempered glass, a transparent plastic, or a transparent film. For example, the cover glass 190 may include any one of sapphire glass and gorilla glass. Further, the cover glass 190 may include any one of polyethylene terephthalate (PET), polycarbonate (PC), polyethylene naphthalate (PEN), polyether sulfone (PES), and polynorbornene (PNB).

The metal plate 160 may be disposed on a rear surface of the display panel 110.

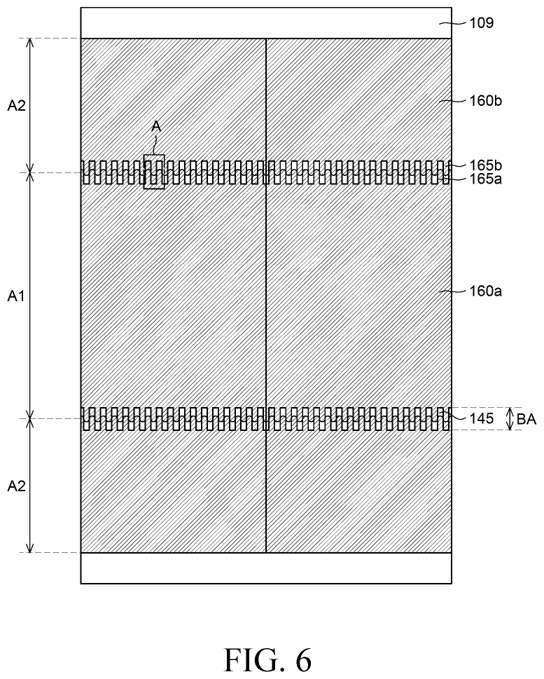

The metal plate 160 according to the exemplary embodiment of the present disclosure is attached to the rear surface of the display panel 110 to maintain a predetermined radius of curvature of the display panel 110 without having an external force, which will be described below with reference to FIGS. 6 to 8.

A first adhesive layer 140a may be disposed between the display panel 110 and the metal plate 160.

The first adhesive layer 140a may be disposed on an entire surface of the display panel 110 and the metal plate 160 excluding a fastening area between the first area A1 and the second area A2. For example, the first adhesive layer 140a may be configured by a pressure sensitive adhesive (PSA), but is not limited thereto.

A second adhesive layer 140b may be disposed between the cover glass 190 and the display panel 110.

The second adhesive layer 140b may be disposed on an entire surface between the cover glass 190 and the display panel 110. The second adhesive layer 140b may be configured by an optical clear adhesive (OCA) or an optical clear resin (OCR), but is not limited thereto.

Referring to FIGS. 3, 4A and 4B, as described above, the cover glass 190 may be disposed above the display panel 110.

For example, the cover glass 190 may be divided into a first part 190a corresponding to the first area A1 and two second parts 190b corresponding to the second area A2.

The second parts 190 may be disposed on both sides of the first part 190a.

The first part 190a may be an area formed as a flat surface, but is not limited thereto, and may be an area formed as a curved surface.

The second part 190b may be an area formed as a curved surface.

When the first part 190a is an area formed as a curved surface, the first part 190a and the second part 190b may be formed by different curved surfaces. In this case, for example, the second part 190b may be formed by a curved surface having a curvature larger than the first part 190a.

Further, the metal plate 160 may be disposed on a rear surface of the display panel 110.

For example, the metal plate 160 may be divided into a first metal plate 160a corresponding to the first area A1 and two second metal plates 160b corresponding to the second area A2.

The second metal plates 160b may be disposed on both sides of the first metal plate 160a, but is not limited thereto.

The first adhesive layer 140a may be disposed between the display panel 110 and the metal plate 160.

In the meantime, instead of the first adhesive layer 140a, cured resin layers 145 and 145′ may be disposed in a boundary area or a fastening area BA between the first area A1 and the second area A2, that is, between the first metal plate 160a and the second metal plate 160b.

For example, the resin layers 145 and 145′ may be configured by pressure sensitive adhesives having a modulus which is lower than a thermal curing resin or the first adhesive layer 140a, but are not limited thereto.

For example, the resin layers 145 and 145′ may be disposed in a direction parallel to the Y-axis direction (see FIG. 1) along the fastening area BA, but are not limited thereto.

The resin layer 145 may be disposed with a width larger than that of the fastening area BA (see FIG. 4A) and the resin layer 145′ may be disposed in a width which is substantially the same as the fastening area BA (see FIG. 4B).

The resin layers 145 and 145′ may make layer-sliding easy to allow the first metal plate 160a and the second metal plate 160b to be easily fastened and after the fastening, the resin layers 145 and 145′ are cured to fix layer-sliding and a motion in a thickness direction. After thermally curing the resin layers 145 and 145′, the resin layers 145 and 145′ may perform an adhering function like the first adhesive layer 140a.

A second adhesive layer 140b may be disposed between the cover glass 190 and the display panel 110.

The display panel 110 may include a back plate 105, an organic light emitting diode layer 115, and a polarization layer 109 which are sequentially laminated.

The back plate 105 is desirably a film member which has a rigidity for protecting the organic light emitting diode layer 115 and elasticity while being easily bent. The back plate 105 is bonded to the organic light emitting diode layer 115 by means of the third adhesive layer 106a which is applied on one surface and has a property of suppressing bubbles from being generated.

The third adhesive layer 106a may be disposed on the entire surface between the organic light emitting diode layer 115 and the back plate 105, but is not limited thereto. For example, the third adhesive layer 106a may be configured by a pressure sensitive adhesive (PSA), but is not limited thereto.

The polarization layer 109 may be disposed above the organic light emitting diode layer 115 by a laminating process.

The polarization layer 109 may be configured by a polarization film and serve to improve the visibility of the display panel 110 by suppressing reflection due to the external light. For example, the polarization layer 109 may be disposed on the top of the display panel 110. In this case, the polarization layer 109 may be bonded to the cover glass 190 by means of the second adhesive layer 140b.

The fourth adhesive layer 106b may be disposed between the polarization layer 109 and the organic light emitting diode layer 115.

The fourth adhesive layer 106b may be disposed on the entire surface between the polarization layer 109 and the organic light emitting diode layer 115, but is not limited thereto. For example, the fourth adhesive layer 106b may be configured by a pressure sensitive adhesive (PSA), but is not limited thereto.

However, the present disclosure is not limited thereto and a touch film which allows the screen to be directly touched to input user information may be attached onto the polarization layer 109. In this case, the second adhesive layer 140b is applied on a surface of the touch film bonded onto the display panel 110 to be bonded to the inner side of the cover glass 190.

Even though it is not illustrated, the encapsulation layer may be disposed below the polarization layer 109.

The encapsulation layer may protect the organic light emitting diode layer 115 from oxygen or moisture.

In some cases, the touch sensor layer is disposed between the polarization layer 109 and the encapsulation layer to implement a touch function in the display panel 110. Such a touch sensor layer is implemented by a touch film to sense the change of a capacitance due to the touch.

The organic light emitting diode layer 115 may be disposed below the encapsulation layer.

The organic light emitting diode layer 115 displays an image corresponding to a data signal supplied from a display driving circuit and for example, may include a substrate and a pixel array.

The back plate 105 may be disposed below the organic light emitting diode layer 115.

The back plate 105 is attached to a lower portion of the organic light emitting diode layer 115 to protect the lower portion of the organic light emitting diode layer 115.

The polarization layer 109, the encapsulation layer, the organic light emitting diode layer 115, and the back plate 105 which have been described above may be defined as the display panel 110.

The display panel 110 is easily bent to be applied for various types of display devices. In the present disclosure, the display panel 110 is attached to the inner side of a U-shaped cover glass 190 in which a side portion is slightly bent to provide a curved display panel 110 which uses not only an upper surface, but also a bent side portion as an active area.

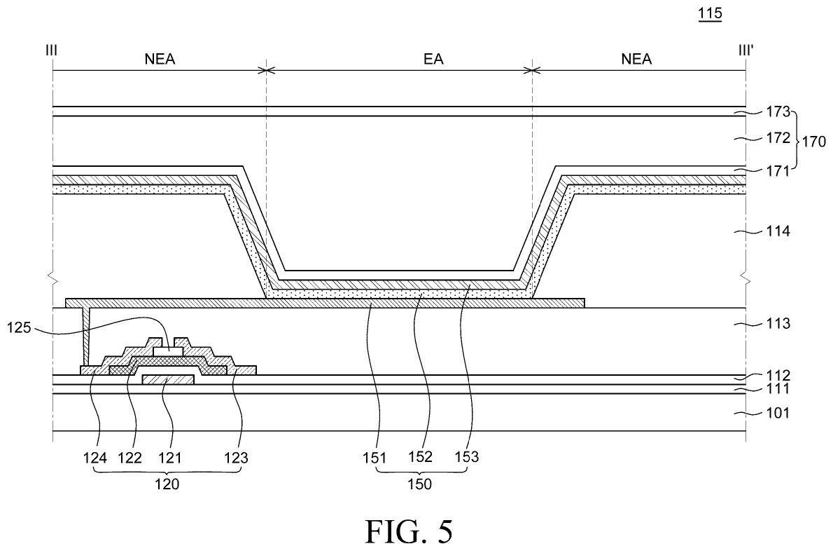

FIG. 5 is a cross-sectional view of an organic light emitting diode layer taken along the line III-III′ of FIG. 1.

Referring to FIG. 5, the organic light emitting diode layer 115 according to the exemplary embodiment of the present disclosure may include a substrate 101, a thin film transistor 120, an over coating layer 113, a bank layer 114, a light emitting diode 150, and an encapsulation unit 170.

The display device may be implemented as a top emission type light emitting display device, but is not limited thereto, and may also be applied to a bottom emission type.

The substrate 101 may support and protect several components of the organic light emitting diode layer 115.

The substrate 101 may be formed of a glass or a plastic material having flexibility.

A buffer layer 111 may be disposed on the substrate 101.

At this time, the buffer layer 111 may improve adhesive strength between layers formed above the buffer layer 111 and the substrate 101 and block alkali components leaked from the substrate 101. The buffer layer 111 may be omitted based on a type or a material of the substrate 101 and a structure and a type of the thin film transistor 120.

The thin film transistor 120 may be disposed above the substrate 101.

The thin film transistor 120 may be used as a driving element of the display device.

The thin film transistor 120 may include a gate electrode 121, an active layer 122, a source electrode 123, and a drain electrode 124.

A gate electrode 121 of the thin film transistor 120 may be disposed above the substrate 101.

A gate insulating layer 112 may be disposed on the gate electrode 121.

The gate insulating layer 112 is a layer for electrically insulating the gate electrode 121 from the active layer 122 and may be formed of an insulating material.

The active layer 122 may be disposed on the gate insulating layer 112.

The active layer 122 may be disposed so as to overlap the gate electrode 121.

An etch stopper 125 may be disposed on the active layer 122. However, the etch stopper 125 may be omitted.

In the meantime, the source electrode 123 and the drain electrode 124 may be disposed above the active layer 122 and the etch stopper 125. The source electrode 123 and the drain electrode 124 may be disposed on the same layer to be spaced apart from each other. The source electrode 123 and the drain electrode 124 may be in contact with the active layer 122 to be electrically connected to the active layer 122, but are not limited thereto and may be electrically connected to the active layer through a contact hole.

The over coating layer 113 may be disposed above the thin film transistor 120.

The over coating layer 113 may protect the thin film transistor 120 and make the step of layers disposed above the substrate 101 gentle. The over coating layer 113 may also be referred to as a planarization layer.

The light emitting diode 150 may be disposed above the over coating layer 113.

At this time, the light emitting diode 150 may include the first electrode 151 disposed on the over coating layer 113, the emission layer 152 disposed on the first electrode 151, and the second electrode 153 disposed on the emission layer 152.

The first electrode 151 may be disposed on the over coating layer 113 so as to cover a part of a top surface. The first electrode 151 may be electrically connected to the thin film transistor 120.

When the display device according to the exemplary embodiment of the present disclosure may be a top emission type display device, the first electrode 151 may be configured to include a reflective layer and a transparent conductive layer disposed on the reflective layer. The reflective layer may reflect light emitted from the light emitting diode 150 upwardly. The reflective layer may be electrically connected to the drain electrode 124 through a contact hole formed in the over coating layer 113. But it is not limited thereto and the reflective layer may be electrically connected to the source electrode 123 through a contact hole formed in the over coating layer 113.

The transparent conductive layer of the first electrode 151 is disposed on the reflective layer to be electrically connected to the drain electrode 124 by means of the reflective layer. The transparent conductive layer may be formed of a conductive material having a high work function to supply holes to the emission layer 152.

The bank layer 114 may be disposed on the first electrode 151 and the over coating layer 113.

The bank layer 114 may be disposed to cover an end in a partial area of the first electrode 151 of the light emitting diode 150 to define an emission area EA and a non-emission area NEA. For example, the bank layer 114 is disposed between the first electrode 151 and the emission layer 152 in the non-emission area NEA to block the generation of the light in the non-emission area NEA.

Further, the bank layer 114 is not disposed in the emission area EA so that the emission layer 152 is immediately located on the first electrode 151 to allow the emission layer 152 to generate light.

The bank layer 114 may be formed of an organic material.

The bank layer 114 includes a top surface, a bottom surface, and a side surface and the top surface may be narrower than the bottom surface. At this time, the top surface of the bank layer 114 is a surface located at the top of the bank layer 114 and may be substantially parallel to the over coating layer 113. The bottom surface of the bank layer 114 may be a surface which is in contact with the over coating layer 113 on the bottom of the bank layer 114. Further, the side surface of the bank layer 114 may be a surface which connects a top surface and a bottom surface of the bank layer 114 and may have an inclined shape toward the bottom surface from the top surface.

The emission layer 152 may be disposed on the first electrode 151 and the bank layer 114. For example, the emission layer 152 may be disposed on the first electrode 151 in the emission area EA and may be disposed on the bank layer 114 in the non-emission area NEA.

The emission layer 152 is a layer for emitting light having a specific color and may include at least one of a red emission layer, a green emission layer, a blue emission layer, and a white emission layer. Further, the emission layer 152 may further include various layers such as a hole transport layer, a hole injection layer, a hole blocking layer, an electron injection layer, an electron blocking layer, or an electron transport layer. The emission layer 152 may be an organic emission layer formed of an organic material, but is not limited thereto. For example, the emission layer 152 may be a quantum dot emission layer or a micro LED.

The emission layer 152 is disposed above the bank layer 114 in the non-emission area NEA so that the emission layer 152 may also be disposed in accordance with a shape of the bank layer 114.

The second electrode 153 may be disposed on the emission layer 152.

The second electrode 153 supplies electrons to the emission layer 152. However, since the display device is a top emission type light emitting display device, the second electrode 153 has a very thin thickness so that the refractive index of the second electrode 153 may not affect the traveling of the light.

As the second electrode 153 is disposed above the emission layer 152 in the non-emission area NEA, the second electrode 153 may also be disposed in accordance with the shape of the emission layer 152.

The encapsulating unit 170 may be disposed above the light emitting diode 150.

The encapsulation unit 170 may be disposed so as to cover the second electrode 153.

The encapsulation unit 170 may protect the light emitting diode 150 from moisture or oxygen permeating from the outside of the display device.

The encapsulation unit 170 may include a first encapsulation layer 171, a second encapsulation layer 172, and a third encapsulation layer 173.

The first encapsulation layer 171 is disposed on the second electrode 153 to suppress the permeation of the moisture or oxygen.

The first encapsulation layer 171 is disposed above the second electrode 153 so that the first encapsulation layer 171 may also be disposed in accordance with the shape of the second electrode 153.

The second encapsulating layer 172 is disposed on the first encapsulating layer 171 to planarize a surface. Further, the second encapsulation layer 172 may cover foreign materials or particles which may be generated during a manufacturing process.

The third encapsulation layer 173 may be disposed on the second encapsulation layer 172.

The third encapsulation layer 173 may suppress permeation of moisture and oxygen, like the first encapsulation layer 171.

In the meantime, the display device according to the exemplary embodiment of the present disclosure is a top emission type light emitting display device so that the display device may be manufactured so as to implement micro cavity. For example, in the display device according to the exemplary embodiment of the present disclosure, a distance between the reflective layer of the first electrode 151 and the second electrode 153 is set to implement the constructive interference for light emitted from the emission layer 152. Therefore, the optical efficiency may be improved.

According to the present disclosure, separate metal plates are attached to a rear surface of the display panel to forcibly fit them together so that a specific radius of curvature may be maintained without external force, which will be described in detail with reference to the drawing.

FIG. 6 is a rear view of a display device of FIG. 4B.

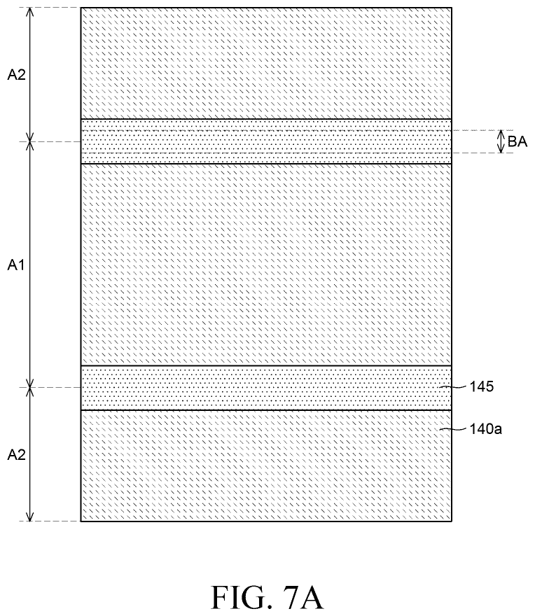

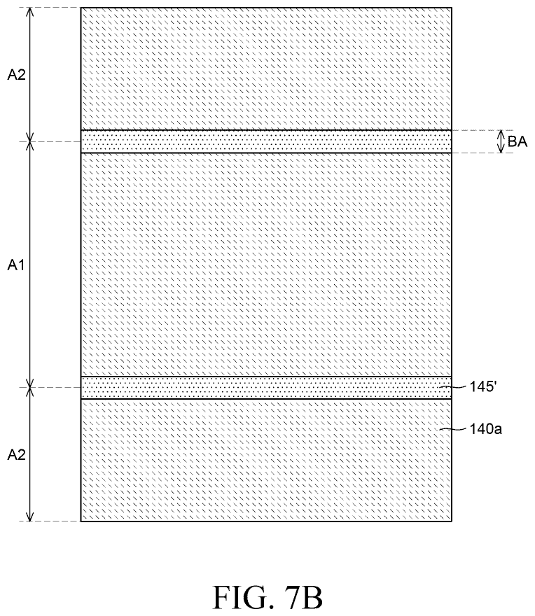

FIG. 7A is a rear view of a first adhesive layer and a resin layer of FIG. 4A.

FIG. 7B is a rear view of a first adhesive layer and a resin layer of FIG. 4B.

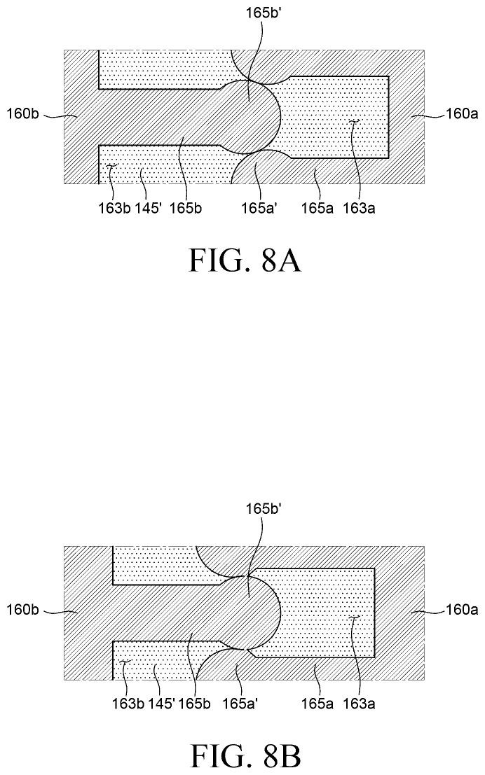

FIGS. 8A and 8B are views enlarging a part A of FIG. 6.

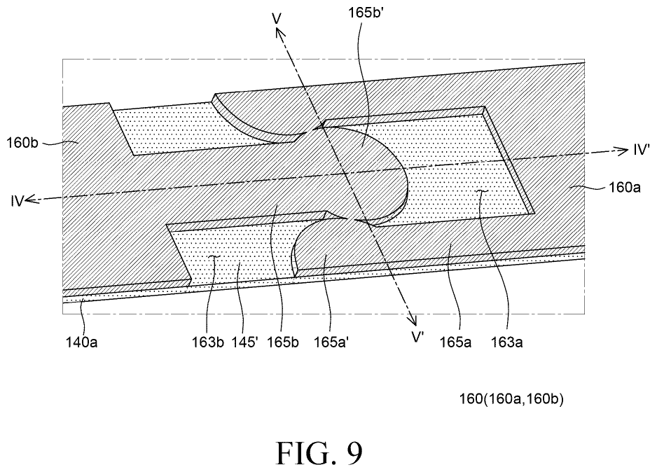

FIG. 9 is a perspective view enlarging a part A of FIG. 6.

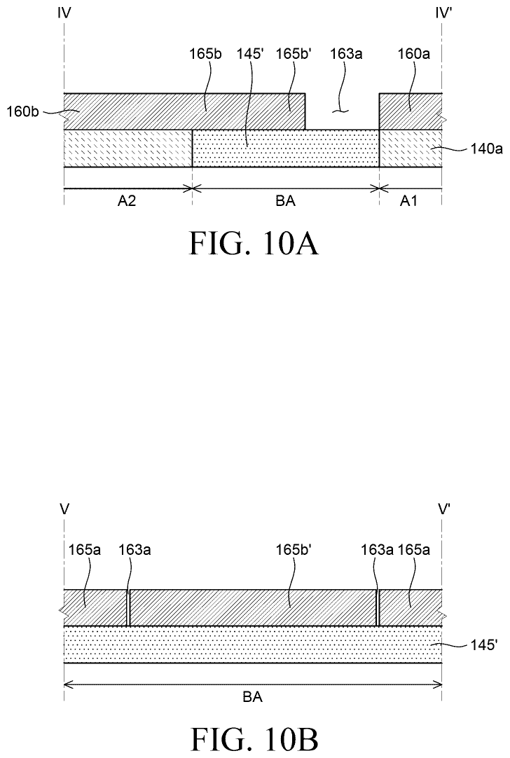

FIG. 10A is a cross-sectional view of a metal plate taken along the line IV-IV′ of FIG. 9.

FIG. 10B is a cross-sectional view of a metal plate taken along the line V-V′ of FIG. 9.

FIG. 8A illustrates a part of a rear surface of the display device before fastening first and second bumps 165a and 165b and first and second slots 163a and 163b of a first metal plate 160a and a second metal plate 160b as an example.

FIG. 8B illustrates a part of a rear surface of the display device after fastening first and second bumps 165a and 165b and first and second slots 163a and 163b of a first metal plate 160a and a second metal plate 160b as an example.

FIG. 9 is a perspective view illustrating a part A of the display device of FIG. 6 and enlarges a part of the metal plate 160 after fastening.

FIGS. 10A and 10B illustrate a cross-section of a metal plate 160 taken along the lines IV-IV′ and V-V′ of FIG. 9 together with a cross-section of the first adhesive layer 140a and the resin layer 145′.

Referring to FIGS. 6 to 10A and 10B, the metal plate 160 may be disposed on the bottom of the display device.

The metal plate 160 of the exemplary embodiment of the present disclosure is a configuration which is attached to the rear surface of the display panel to maintain a predetermined radius of curvature of the display panel without an external force.

For example, the metal plate 160 may be configured by Invar which is an iron/nickel alloy, but is not limited thereto and the metal plate 160 of the present disclosure may be configured by aluminum (Al), stainless steel (STS), or copper (Cu).

Further, for example, the metal plate 160 may include a first metal plate 160a corresponding to the first area A1 and two second metal plates 160b corresponding to the second area A2. For example, one second metal plate 160b is disposed on one side of the first metal plate 160a and one second metal plate 160b on the other side of the first metal plate 160a.

However, the present disclosure is not limited thereto so that when the second area A2 is disposed only on one side of the first area A1, the metal plate 160 may include one second metal plate 160b on one side of the first metal plate 160a.

For example, the first metal plate 160a may include a plurality of first bumps 165a which protrudes toward the second metal plate 160a and a plurality of first slots 163a between the plurality of first bumps 165a. The plurality of first bumps 165a and the plurality of first slots 163a may be disposed on both sides of the first metal plate 160a. Further, the plurality of first bumps 165a and the plurality of first slots 163a may be alternately disposed.

For example, the second metal plate 160b may include a plurality of second bumps 165b which protrudes toward the first metal plate 160a and a plurality of second slots 163b between the plurality of second bumps 165b. The plurality of second bumps 165b and the plurality of second slots 163b may be disposed on one side of the second metal plate 160b which is directed to the first metal plate 160a. The plurality of second bumps 165b and the plurality of second slots 163b may be alternately disposed.

For example, the first slot 163a may have a width and a length enough to accommodate the second bump 165b and the second slot 163b may have a width and a length enough to accommodate the first bump 165a.

At this time, the first bump 165a may have a first end portion 165a′ protruding toward the second slot 163b and the first end portion 165a′ may have a circular shape with an increased width.

Further, the second bump 165b may have a second end portion 165b′ protruding toward the first slot 163a and the second end portion 165b′ may have a circular shape with an increased width.

The first end portion 165a′ of the first bumps 165a and the second end portion 165b′ of the second bump 165b are in contact with each other before being fastened and cannot be inserted into the second slot 163b and the first slot 163a. Accordingly, when the first metal plate 160a and the second metal plate 160b are fastened, the first end portion 165a′ of the first bump 165a and the second end portion 165b′ of the second bump 165b are forcibly fitted to be fastened with the second slot 163b and the first slot 163a. At this time, in a forcibly fitted state, a part of the first end portion 165a′ of the first bump 165a and a part of the second end portion 165b′ of the second bump 165b may be in contact with each other. The restoring force of the display panel is offset by the stress of the first metal plate 160a and the second metal plate 160b which are forcibly fitted together, so that the display panel is attached to the cover glass 190 while maintaining the local curvature.

As described above, the first end portion 165a′ of the first bump 165a and the second end portion 165b′ of the second bump 165b are forcibly fitted to be fastened so that the display panel may maintain a specific radius of curvature without an external force.

The mold, laser cutting, or etching may be applied to the processing of the first metal plate 160a and the second metal plate 160b.

In the meantime, the first adhesive layer 140a may be disposed between the display panel 110 and the metal plate 160.

For example, the first adhesive layer 140a may not be disposed in a fastening area BA between the first area A1 and the second area A2 and the resin layers 145 and 145′ may be disposed in the fastening area BA. The resin layer 145 may be disposed with a width larger than that of the fastening area BA (see FIG. 7A) and the resin layer 145′ may be disposed in a width which is substantially the same as the fastening area BA (see FIG. 7B). Hereinafter, for the convenience of description, as illustrated in FIG. 7B, an example that the resin layer 145′ is disposed with the substantially same width as the fastening area BA will be described.

For example, the fastening area BA is an area in which the first and second bumps 165a and 165b and the first and second slots 163a and 163b of the first and second metal plates 160a and 160b are disposed.

The fastening area BA is a location where the curvature of the first area A1 and the curvature of the second area A2 are sharply changed and in the related art, the cover glass 190 and the display panel are separated in the fastening area BA.

Recently, in addition to rollable, bendable, and curved display devices which have a specific curvature constant in the entire display panel, display devices which have a curvature only in a specific part (portion) of the display panel are being developed. In this case, after attaching the display panel to the cover glass, separation occurs between the cover glass and the display panel in the local curvature portion due to the reaction force of the bent display panel. Specifically, when implementing multiple curvatures, separation occurs between the cover glass and the display panel due to the various curvatures, and also, when evaluating high-temperature reliability, separation easily occurs between the cover glass and the display panel at high temperatures due to continuous restoring force.

Therefore, according to the exemplary embodiment of the present disclosure, after attaching the display panel to the cover glass 190, in order to remove the reaction force of the display panel, a residual stress is applied to the display panel to maintain a shape of the display panel to be the same as the shape of the cover glass 190.

Therefore, according to the exemplary embodiment of the present disclosure, as described above, the metal plate 160 is disposed on a rear surface of the display panel. In this case, in a state in which the first metal plate 160a and the second metal plate 160b are disposed such that the first end portion 165a′ of the first bump 165a and the second end portion 165b′ of the second bump 165b are located in the fastening area BA, the first end portion 165a′ of the first bump 165a and the second end portion 165b′ of the second bump 165b are forcibly fitted to be fastened. Further, according to the exemplary embodiment of the present disclosure, when the first end portion 165a′ of the first bump 165a and the second end portion 165b′ of the second bump 165b are forcibly fitted to be fastened, the resin layer 145′ disposed in the fastening area BA is cured to be fixed to maintain the specific radius of curvature. That is, in the fastening area BA between the first metal plate 160a and the second metal plate 160b, the cured resin layer 145′ may be disposed instead of the first adhesive layer 140a. Accordingly, when the first end portion 165a′ of the first bump 165a and the second end portion 165b′ of the second bump 165b are forcibly fitted to be fastened, the bent display panel may maintain a specific radius of curvature, by the first metal plate 160a and the second metal plate 160b.

Further, for example, the resin layer 145′ may be disposed in the form of a bar along the fastening area BA, but is not limited thereto.

As described above, according to the exemplary embodiment of the present disclosure, a flat display panel is not attached to the curved cover glass 190, but the metal plate 160 which is divided into the first metal plate 160a and the second metal plate 160b is attached onto a rear surface of the display panel and is forcibly fitted to attach the curved display panel to the cover glass 190. At this time, in the fastening area BA, a residual stress occurring when the first end portion 165a′ of the first bump 165a and the second end portion 165b′ of the second bump 165b are forcibly fitted to be fastened offsets a restoring force which allows the curved display panel to be returned to its original state.

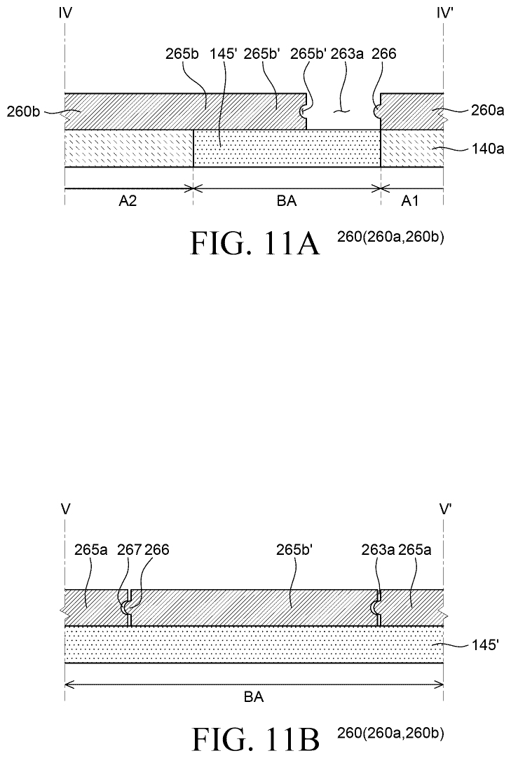

FIGS. 11A and 11B are cross-sectional views of a metal plate according to another exemplary embodiment of the present disclosure.

FIGS. 11A and 11B illustrate a cross-section of a metal plate 260 according to another exemplary embodiment of the present disclosure taken along the lines IV-IV′ and V-V′ of FIG. 9 together with a cross-section of the first adhesive layer 140a and the resin layer 145′.

Referring to FIG. 11A, and 11B, a metal plate 260 according to another exemplary embodiment of the present disclosure, for example, may be divided into a first metal plate 260a corresponding to a first area A1 and two second metal plates 260b corresponding to a second area A2.

For example, the first metal plate 260a may include a plurality of first bumps 265a which protrudes toward the second metal plate 260b and a plurality of first slots 263a between the plurality of first bumps 265a. The plurality of first bumps 265a and the plurality of first slots 263a may be alternately disposed.

For example, the second metal plate 260b may include a plurality of second bumps 265b which protrudes toward the first metal plate 260a and a plurality of second slots 263b between the plurality of second bumps 265b. The plurality of second bumps 265b and the plurality of second slots 263b may be alternately disposed.

At this time, the first bump 265a may have a first end portion 265a′ which protrudes toward the second slot 263b and the second bump 265b may have a second end portion 265b′ which protrudes toward the first slot 263a.

For example, when the first metal plate 260a and the second metal plate 260b are fastened, the first end portion 265a′ of the first bump 265a and the second end portion 265b of the second bump 265b are forcibly fitted to be fastened with the second slot 263b and the first slot 263a. The first metal plate 260a and the second metal plate 260b may be restrained in the horizontal direction by the forcible fitting in the direction of the plane.

On a side surface of the first metal plate 260a including the first bump 265a, a third bump 266 which protrudes toward a third slot 267 of a side surface of the second metal plate 260b including the second bump 265b may be provided. The third bump 266 and the third slot 267 may configure a forcible fitting structure in a thickness direction. The first metal plate 260a and the second metal plate 260b may be restrained in a vertical direction by the forcible fitting in the thickness direction. However, the present disclosure is not limited thereto and a third bump may be provided on a side surface of the second metal plate 260b including the second bump 265b and a third slot may be provided on a side surface of the first metal plate 260a including the first bump 265a.

The first adhesive layer 140a may be disposed between the display panel and the metal plate 260.

That is, in the fastening area BA between the first metal plate 260a and the second metal plate 260b, the cured resin layer 145′ may be disposed instead of the first adhesive layer 140a.

As described above, according to another exemplary embodiment of the present disclosure, not only the forcible fitting in the planar direction, but also a forcible fitting structure in the thickness direction is provided so that the fastening may be more firmly maintained than an exemplary embodiment described above. Therefore, the separation between the cover glass and the display panel in the local curvature portion may be more effectively suppressed.

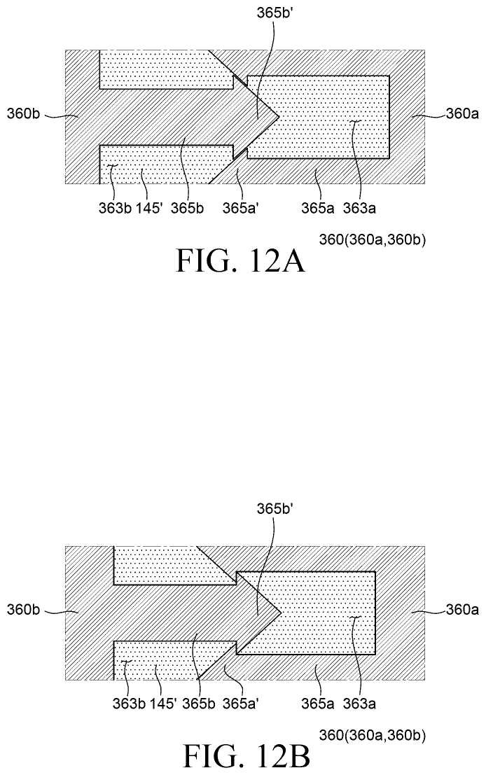

FIGS. 12A and 12B are views illustrating a part of a metal plate according to still another exemplary embodiment of the present disclosure.

FIG. 12A illustrates a part of a rear surface of a display device before fastening a first metal plate 360a and a second metal plate 360b as an example.

FIG. 12B illustrates a part of a rear surface of a display device after fastening a first metal plate 360a and a second metal plate 360b as an example.

Referring to FIGS. 12A and 12B, a metal plate 360 according to still another exemplary embodiment of the present disclosure may be divided (separated) into a first metal plate 360a corresponding to a first area and two second metal plates 360b corresponding to a second area.

For example, the first metal plate 360a may include a plurality of first bumps 365a which protrudes toward the second metal plate 360b and a plurality of first slots 363a between the plurality of first bumps 363a. The plurality of first bumps 365a and the plurality of first slots 363a may be alternately disposed.

For example, the second metal plate 360b may include a plurality of second bumps 365b which protrudes toward the first metal plate 360a and a plurality of second slots 363b between the plurality of second bumps 365b. The plurality of second bumps 365b and the plurality of second slots 363b may be alternately disposed.

At this time, the first bump 365a may have a first end portion 365a′ protruding toward the second slot 363b and the first end portion 365a′ may have a triangular shape with an increased width.

Further, the second bump 365a may have a second end portion 365b′ protruding toward the first slot 363a and the second end portion 365b′ may have a triangular shape with an increased width.

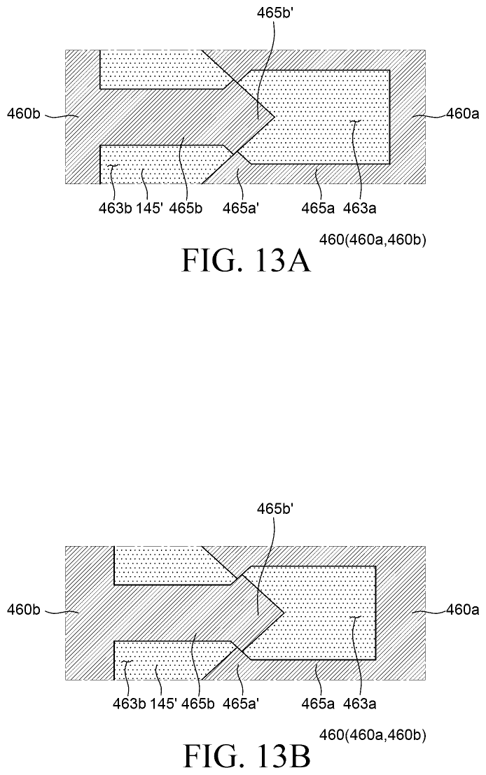

FIGS. 13A and 13B are views illustrating a part of a metal plate according to still another exemplary embodiment of the present disclosure.

FIG. 13A illustrates a part of a rear surface of a display device before fastening a first metal plate 460a and a second metal plate 460b as an example.

FIG. 13B illustrates a part of a rear surface of a display device after fastening a first metal plate 460a and a second metal plate 460b as an example.

Referring to FIGS. 13A and 13B, a metal plate 460 according to still another exemplary embodiment of the present disclosure may be divided (separated) into a first metal plate 460a corresponding to a first area and two second metal plates 460b corresponding to a second area.

For example, the first metal plate 460a may include a plurality of first bumps 465a which protrudes toward the second metal plate 460b and a plurality of first slots 463a between the plurality of first bumps 465a. The plurality of first bumps 465a and the plurality of first slots 463a may be alternately disposed.

For example, the second metal plate 460b may include a plurality of second bumps 465b which protrudes toward the first metal plate 460a and a plurality of second slots 463b between the plurality of second bumps 465b. The plurality of second bumps 465b and the plurality of second slots 463b may be alternately disposed.

At this time, the first bump 465a may have a first end portion 465a′ protruding toward the second slot 463b and the first end portion 465a′ may have a diamond or rhombus shape with an increased width. However, it is not limited thereto and may have various shapes, such as a trapezoidal shape or an oval shape.

Further, the second bump 465a may have a second end portion 465b′ protruding toward the first slot 463a and the second end portion 465b′ may have a diamond shape or a rhombus shape with an increased width. However, it is not limited thereto and may have various shapes, such as polygons such as a trapezoidal shape, or an oval shape.

Hereinafter, a method of attaching a display panel to a curved cover glass will be described in detail with reference to the drawings.

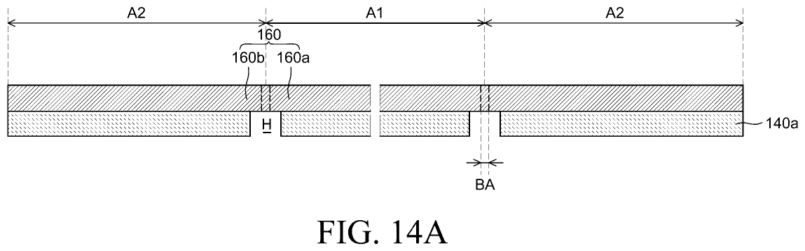

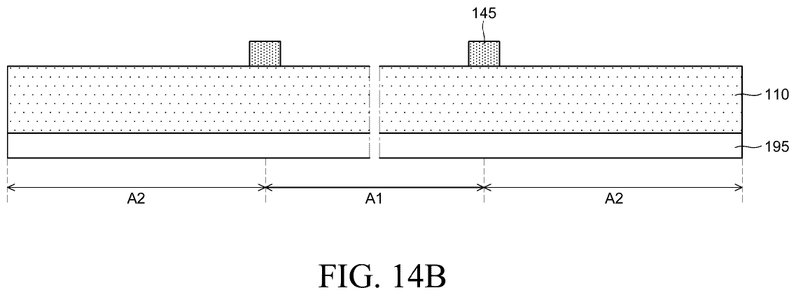

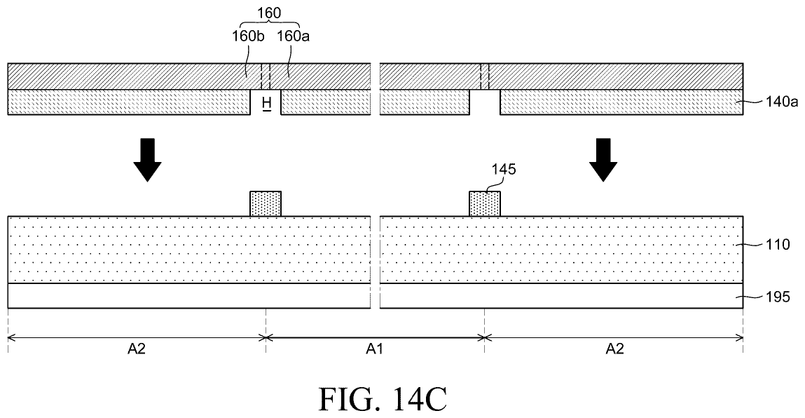

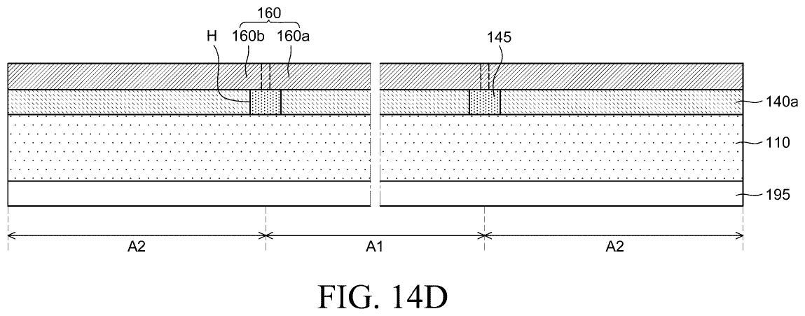

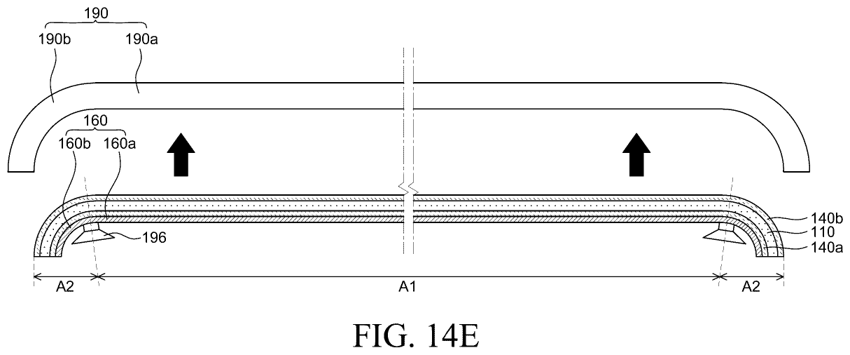

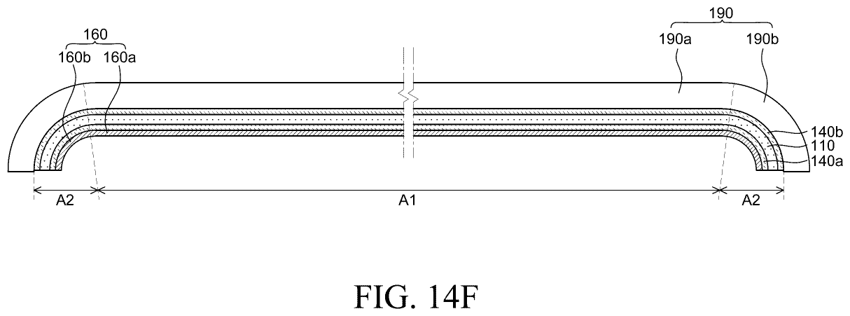

FIGS. 14A to 14F are cross-sectional views sequentially illustrating a method of attaching a display panel to a curved cover glass according to an exemplary embodiment of the present disclosure.

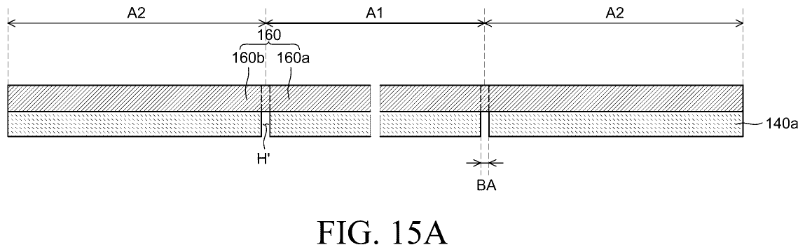

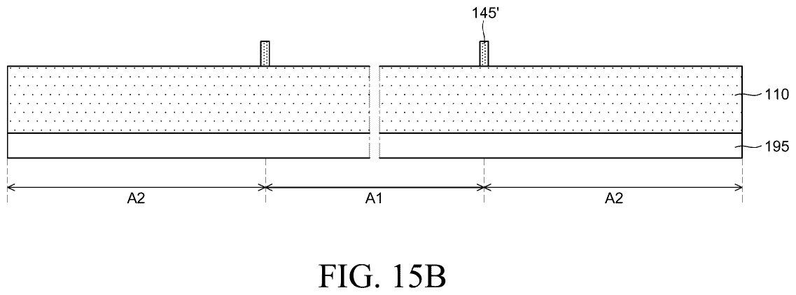

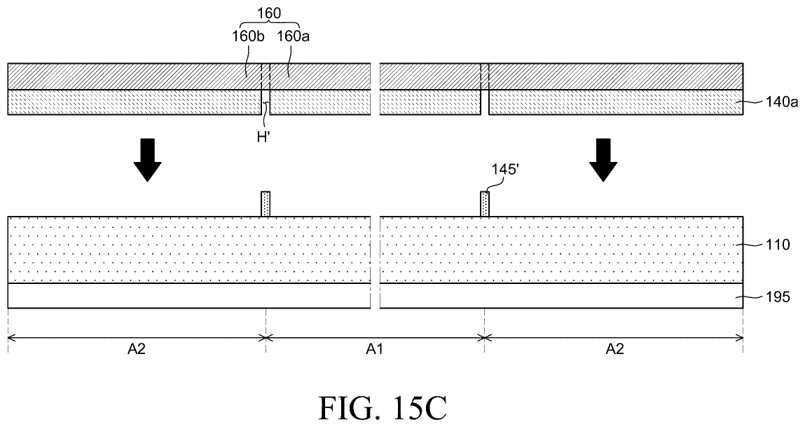

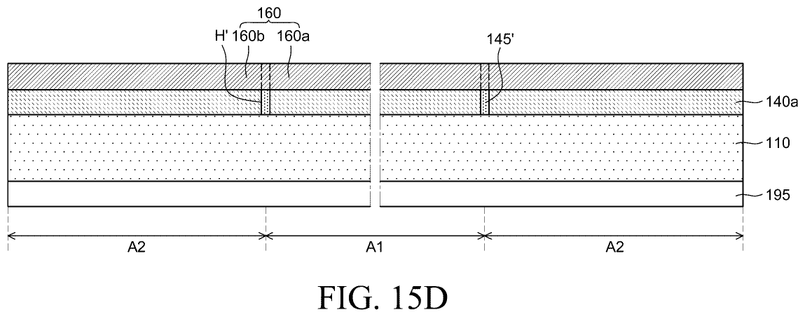

FIGS. 15A to 15D are cross-sectional views illustrating a part of another method of attaching a display panel to a curved cover glass according to an exemplary embodiment of the present disclosure.

FIGS. 14A to 14F illustrate an example that the resin layer 145 is formed to have a width larger than that of the fastening area BA and FIGS. 15A to 15D illustrate an example that the resin layer 145′ and the fastening area BA are formed to have substantially the same width. The other configuration and methods are substantially the same so that description for FIGS. 15A to 15D will be made in the description of FIGS. 14A to 14F.

Referring to FIGS. 14A, 14B, 15A, and 15B, a display panel 110 and a metal plate 160 to be attached to a rear surface of the display panel 110 are prepared.

The display panel 110 according to an exemplary embodiment of the present disclosure may be a flexible display panel and may include an organic light emitting diode layer to include a polarization layer and an encapsulation layer.

The display panel 110 may be divided into a first area A1 and a second area A2 along the curved cover glass, but is not limited thereto.

A carrier glass 195 may be attached to the rear surface of the display panel 110 to transport and protect the display panel 110.

The metal plate 160 is a configuration which is attached to the rear surface of the display panel 110 to maintain a predetermined radius of curvature of the display panel 110 without an external force. The metal plate may be divided into a first metal plate 160a corresponding to a first area A1 and a second metal plate 160b corresponding to a second area A2, but it is not limited thereto.

The first adhesive layer 140a may be attached to the rear surface of the metal plate 160.

The first adhesive layer 140a may not be disposed in the vicinity of the fastening area BA between the first area A1 and the second area A2, but is not limited thereto. For example, predetermined grooves (or empty spaces) H and H′ in which the first adhesive layer 140a is not disposed may be provided in the vicinity of the fastening area BA between the first area A1 and the second area A2. In FIG. 14A, the groove H may be formed to have a width larger than that of the fastening area BA and in FIG. 15A, the groove H′ may be formed to have a width which is substantially the same as the first fastening area BA.

For example, the first adhesive layer 140a may be configured by a pressure sensitive adhesive (PSA), but is not limited thereto.

In the meantime, the resin layers 145 and 145′ may be disposed on the top surface of the display panel 110 corresponding to the grooves H and H′.

Further, for example, the resin layers 145 and 145′ may be disposed in the form of a bar along the grooves H and H′, but is not limited thereto.

Next, referring to FIGS. 14C, 14D, 15C and 15D, the metal plate 160 may be attached above the display panel 110 in which the resin layers 145 and 145′ are disposed using the first adhesive layer 140a.

At this time, the display panel 110 may have a reverse curvature state to the plane or the cover glass. The resin layers 145 and 145′ may be located in the fastening area BA in which the first adhesive layer 140a is not disposed, but is not limited thereto and may partially overlap the first adhesive layer 140a.

When the metal plate 160 is attached to the display panel 110, the first metal plate 160a and the second metal plate 160b may not be fastened yet.

Next, referring to FIG. 14E, a tool 196, such as a tool tip, may be attached to the rear surface of the metal plate 160 bonded to the display panel 110.

The tool 196 may be attached to the fastening area BA between the first metal plate 160a and the second metal plate 160b.

The tool 196 may suppress the motion in the thickness direction when the first metal plate 160a and the second metal plate 160b are fastened and thermally cure the resin layers 145 and 145′.

The tool 196 may serve to apply a pressure and apply heat for a while during the fastening process and may be removed after the fastening process.

For example, for the purpose of easiness of the forcible fitting, the first metal plate 160a and the second metal plate 160b are forcibly fitted to be fastened while compressing the fastening area BA using the tool 196.

Next, the resin layers 145 and 145′ may be thermally cured using the tool 196. Therefore, the unfastening of the first metal plate 160a and the second metal plate 160b which are fastened may be suppressed, the layer sliding motion may be suppressed, and the motion in the thickness direction may also be suppressed.

At this time, even though the external force is removed, the first metal plate 160a and the second metal plate 160b are forcibly fitted and the resin layers 145 and 145′ are cured to maintain the local curvature.

Next, referring to FIG. 14F, after removing the carrier glass using a reverser, the display panel 110 and the metal plate 160 are bonded along the curvature of the curved cover glass 190.

The exemplary embodiments of the present disclosure can also be described as follows:

According to an aspect of the present disclosure, there is provided a display device. The display device includes a display panel including a plurality of sub pixels, a cover glass disposed above the display panel, the cover glass comprising a first area and a second area and a metal plate disposed below the display panel, the metal plate comprising a first metal plate corresponding to the first area and a second metal plate corresponding to the second area, the first metal plate and the second metal plate may be forcibly fitted together in a fastening area between the first area and the second area to mechanically couple the first metal plate and the second metal plate.

The first area may be a flat area and the second area may be a curved area.

The first area and the second area may be curved areas having different curvatures.

The display device may further comprise a first adhesive layer disposed between the display panel and the metal plate; and a second adhesive layer disposed between the cover glass and the display panel, the first adhesive layer may be configured by a pressure-sensitive adhesive (PSA) and the second adhesive layer may be configured by an optical clear adhesive (OCA) or an optical clear resin (OCR).

The display device may further comprise a resin layer which is disposed between the display panel and the metal plate of the fastening area and the resin layer is configured by a thermal curing resin or a pressure sensitive adhesive (PSA) having a modulus lower than that of the first adhesive layer.

The metal plate may be configured by any one of invar, aluminum (Al), stainless steel (STS), and a copper (Cu).

The first metal plate may include a plurality of first bumps protruding toward the second metal plate and a plurality of first slots disposed between the first bumps, the first bumps and the first slots are alternately arranged.

The second metal plate may include a plurality of second bumps protruding toward the first metal plate and a plurality of second slots disposed between the plurality of second bumps, the second bumps and the second slots are alternately arranged.

The first slot may have a width and a length enough to accommodate the second bump and the second slot may have a width and a length sufficient to accommodate the first bump.

The first bump may have a first end portion which protrudes to be wider toward the second slot and the second bump may have a second end portion which protrudes to be wider toward the first slot.

The first end portion and the second end portion may have shapes of a circular shape, an oval shape, a triangular shape, a diamond, or a trapezoidal shape.

The first metal plate and the second metal plate may be fastened by forcibly fitting the first end portion of the first bump into the second slot and the second end portion of the second bump into the first slot.

The first and second bumps and the first and second slots may be disposed in the fastening area.

A third bump may be provided on a side surface of the first metal plate including the first bump and a third slot may be provided on a side surface of the second metal plate including the second bump.

A third bump may be provided on a side surface of the second metal plate including the second bump and a third slot may be provided on a side surface of the first metal plate including the first bump.

The third bump may protrude toward the third slot and the third bump and the third slot configure a forcible fitting structure in a thickness direction.

According to another aspect of the present disclosure, there is provided a display device. The display device includes a display panel including a plurality of sub pixels, a cover glass disposed above the display panel, the cover glass comprising a first area having a first curvature and a second area having a second curvature greater than the first curvature and a metal plate disposed below the display panel, the metal plate comprising a first metal plate corresponding to the first area and a second metal plate corresponding to the second area, the first metal plate and the second metal plate are forcibly fitted together and fastened in a fastening area between the first area and the second area.

The first metal plate may include a plurality of first bumps which protrudes toward the second metal plate and a plurality of first slots between the plurality of first bumps, the plurality of first bumps and the plurality of first slots may be alternately disposed, the second metal plate may include a plurality of second bumps which protrudes toward the first metal plate and a plurality of second slots between the plurality of second bumps, and the plurality of second bumps and the plurality of second slots may be alternately disposed.

The first bump may have a first end portion which protrudes to be wider toward the second slot and the second bump may have a second end portion which protrudes to be wider toward the first slot.

The first metal plate and the second metal plate may be fastened by forcibly fitting the first end portion of the first bump and the second end portion of the second bump.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a plurality of sub pixels;
a cover glass disposed above the display panel, the cover glass comprising a first area and a second area; and
a metal plate disposed below the display panel, the metal plate comprising a first metal plate corresponding to the first area and a second metal plate corresponding to the second area,
wherein the first metal plate and the second metal plate are mechanically coupled together in a force fit at a fastening area between the first area and the second area.

2. The display device according to claim 1, wherein the first area is a flat area and the second area is a curved area.

3. The display device according to claim 1, wherein the first area and the second area are each curved areas having different curvatures.

4. The display device according to claim 1, further comprising:
a first adhesive layer disposed between the display panel and the metal plate; and
a second adhesive layer disposed between the cover glass and the display panel,
wherein the first adhesive layer is a pressure-sensitive adhesive and the second adhesive layer is an optical clear adhesive or an optical clear resin.

5. The display device according to claim 4, further comprising:
a resin layer disposed between the display panel and the metal plate at the fastening area, wherein the resin layer is a thermal curing resin or a pressure sensitive adhesive having a modulus of elasticity lower than a modulus of elasticity of the first adhesive layer.

6. The display device according to claim 1, wherein the metal plate is any one of invar, aluminum, stainless steel, and copper.

7. The display device according to claim 1, wherein the first metal plate includes:
a plurality of first bumps protruding toward the second metal plate; and
a plurality of first slots disposed between the plurality of first bumps,
wherein the plurality of first bumps and the plurality of first slots are alternately arranged.

8. The display device according to claim 7, wherein the second metal plate includes:
plurality of second bumps protruding toward the first metal plate; and
a plurality of second slots disposed between the plurality of second bumps,
wherein the plurality of second bumps and the plurality of second slots are alternately arranged.

9. The display device according to claim 8, wherein one of the plurality of first slots has a width and a length to accommodate a corresponding one of the plurality of second bumps and one of the plurality of second slots has a width and a length to accommodate a corresponding one of the plurality of first bumps.

10. The display device according to claim 8, wherein one of the plurality of first bumps has a first end portion which protrudes to be wider toward a corresponding one of the plurality of second slots and one of the plurality of second bumps has a second end portion which protrudes to be wider toward a corresponding one of the plurality of first slots.

11. The display device according to claim 10, wherein the first end portion and the second end portion are a circular shape, an oval shape, a triangular shape, a diamond shape, or a trapezoidal shape.

12. The display device according to claim 10, wherein the first end portion is configured to be force fit into the corresponding one of the plurality of second slots and the second end portion is configured to be force fit into the corresponding one of the plurality of first slots to mechanically couple the first metal plate to the second metal plate.

13. The display device according to claim 8, wherein the plurality of first bumps, the plurality of second bumps, the plurality of first slots, and the plurality of second slots are disposed in the fastening area.

14. The display device according to claim 8, wherein a third bump is provided on a side surface of the first metal plate including at least one of the plurality of first bumps and a third slot is provided on a side surface of the second metal plate including at least one of the plurality of second bumps.

15. The display device according to claim 8, wherein a third bump is provided on a side surface of the second metal plate including at least one of the plurality of second bumps and a third slot is provided on a side surface of the first metal plate including at least one of the plurality of first bumps.

16. The display device according to claim 14, wherein the third bump protrudes toward the third slot and the third bump and the third slot are configured to be coupled in a force fit in a thickness direction.

17. A display device, comprising:
a display panel including a plurality of sub pixels;
a cover glass disposed above the display panel, the cover glass comprising a first area having a first curvature and a second area having a second curvature greater than the first curvature; and
a metal plate disposed below the display panel, the metal plate comprising a first metal plate corresponding to the first area and a second metal plate corresponding to the second area,
wherein the first metal plate and the second metal plate are mechanically coupled together in a force fit at a fastening area between the first area and the second area.

18. The display device according to claim 17, wherein the first metal plate includes a plurality of first bumps which protrude toward the second metal plate and a plurality of first slots between the plurality of first bumps, the plurality of first bumps and the plurality of first slots are alternately disposed, the second metal plate includes a plurality of second bumps which protrude toward the first metal plate and a plurality of second slots between the plurality of second bumps, and the plurality of second bumps and the plurality of second slots are alternately disposed.

19. The display device according to claim 18, wherein one of the plurality of first bumps has a first end portion which protrudes to be wider toward a corresponding one of the plurality of second slots and one of the plurality of second bumps has a second end portion which protrudes to be wider toward a corresponding one of the plurality of first slots.

20. The display device according to claim 19, wherein the first end portion and the second end portion are configured to be force fit together to fasten the first metal plate and the second metal plate together.
